(19) United States
(12) Patent Application Publication
(10) Pub. No.: US 2025/0151502 A1
(43) Pub. Date: May 8, 2025

(54) SEE-THROUGH LED DISPLAYS AND METHODS RELATED THERETO

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/939,229

(22) Filed: Nov. 6, 2024

Related U.S. Application Data
(60) Provisional application No. 63/597,204, filed on Nov. 8, 2023.

(51) Int. Cl. H10H 29/855; H10H 29/01

(52) U.S. Cl. CPC H10H 29/8552; H10H 29/012; H10H 29/0363

(57) ABSTRACT

A display comprises a plurality of LEDs on a substrate. Each pixel of the display comprises one or more LEDs of the plurality of LEDs and a transparent region of the display. The transparent region transmits light external to the display through the display.

### CROSS-REFERENCE TO RELATED APPLICATION

This application claims the benefit of U.S. Provisional Patent Application No. 63/597,204, filed Nov. 8, 2023, which is hereby incorporated by reference herein in its entirety.

### FIELD

The present disclosure relates to display devices, and in particular may relate to virtual reality, augmented reality, or mixed reality devices, and methods of manufacturing the same.

### BACKGROUND

Augmented reality (AR) displays may have a complex assembly of lenses, mirrors, and waveguides to present an image from a display to a viewing area in front of eyes of a viewer, and may have a limited viewing angle and brightness. Accordingly, there exists a need for improved AR displays and methods of manufacturing the same.

### SUMMARY

Embodiments herein provide for a display or an augmented reality device (e.g., glasses with a display in a viewing area of the glasses) that enables light to pass through between pixels of the display for a viewer to see a real life image or surrounding. In some embodiments, the display is an LED display (e.g., micro LED display) with an active area of the display including the LEDs (e.g., portion of the display that actively emits light generated from the LEDs) being opaque and blocking or preventing external light from passing through the display, while at least a portion of an inactive area (e.g., non-emissive portion that does not actively emit light generated from the LEDs) of the display is transparent and enables external light to pass through the display. Advantageously, the embodiments may help enable a higher efficiency, higher-brightness display in a viewing area of the user over conventional augmented reality devices that may use an assembly for optical delivery of an image of a display to a viewing area of the user or may use a transparent OLED display having limited brightness and pixel size limitations.

A first general aspect includes a method of forming a display including forming a plurality of LEDs on a substrate. Each pixel of the display includes one or more of the plurality of LEDs. The method further includes forming a transparent region of the display. The transparent region transmits light external to the display through the display.

A second general aspect includes a method of forming a display including bonding a first layer comprising a plurality of first LEDs and a second layer comprising a plurality of second LEDs. The plurality of first LEDs emit light of a first color, and the plurality of second LEDs emit light of a second color different than the first color. Each pixel of the display comprises a corresponding first LED from the first layer and a corresponding second LED from the second layer. A transparent region between pixels transmits light external to the display through the display. The method may further include bonding a third layer comprising a plurality of third LEDs to the bonded first and second layers. The plurality of third LEDs may emit light of a third color, the third color being different than the first color and the second color. Each pixel of the display may further comprise a corresponding third LED from the third layer. In some embodiments, the first layer further comprises one or more singulated chips (e.g., Si chips, control devices, etc.).

Implementations of the method according to the second general aspect may include one or more of the following features. In some embodiments, the plurality of first LEDs and the plurality of second LEDs overlap when viewed from top down or bottom up. The plurality of first LEDs and the plurality of second LEDs may be edge-emitting LEDs. Each edge-emitting LED may have a corresponding mirror to reflect light emitted from the edge-emitting LEDs to exit a display surface. In some embodiments, the plurality of first LEDs, the plurality of second LEDs, and the plurality of third LEDs overlap when viewed from top down or bottom up. In some embodiments, the plurality of first LEDs, the plurality of second LEDs, and the plurality of third LEDs are edge-emitting LEDs. Each edge-emitting LED may have a corresponding mirror to reflect light emitted from the edge-emitting LEDs to exit a display surface. In some embodiments, the plurality of first LEDs and the plurality of second LEDs may be edge-emitting LEDs, and the plurality of third LEDs may be surface-emitting LEDs. Each edge-emitting LED may have a corresponding mirror to reflect light emitted from the edge-emitting LEDs to exit a display surface.

Implementations of the methods according to first and second general aspect may further include forming a plurality of passive light blockers. In some embodiments, each passive light blocker may overlap with the one or more LEDs of a corresponding pixel of the display when viewed from top down or bottom up. The plurality of passive light blockers may prevent light external to the display from transmitting through the display in a region corresponding to the one or more LEDs of the corresponding pixel. In some embodiments, each passive light blocker may comprise a metal layer. In some embodiments, each passive light blockers covers a bottom and side surfaces of each LED. Each passive light blocker may prevent light external to the display from transmitting through a corresponding LED. In some embodiments, each passive light blocker comprises a singulated chip (e.g., Si chip, control device, etc.). Transparent wiring electrically connecting one or more singulated chips may overlap with a corresponding transparent region of the display when viewed from top down or bottom up.

Implementations of the methods according to first and second general aspect may further include forming a controllable light blocker. The controllable light blocker may overlap with a transparent region of the display when viewed from top down or bottom up. The controllable light blocker may comprise a switchable material. In response to applying a bias to corresponding electrodes that are electrically connected to the switchable material, the switchable material may transmit light external to the display through the display in the transparent region of the display. In response to not applying a bias to the corresponding electrodes that are electrically connected to the switchable material, the switchable material may block light external to the display from transmitting through the display in the transparent region of the display. In some embodiments, the switchable material comprises liquid crystal material.

Implementations of the methods according to first and second general aspect may include one or more of the following features. Corresponding LEDs of each pixel of the display may be formed in a center portion, in one corner, in corresponding corners, or in one side of a corresponding pixel area when viewed from top down or bottom up. In some embodiments, the method may further comprise attaching a plurality of lenses to the display, wherein the plurality of lenses overlap the plurality of LEDs when viewed from top down or bottom up. Each lens may correspond to a pixel of the display. In some embodiments, the method may further comprise attaching a plurality of first lenses and second lenses to the display. The plurality of first lenses may overlap the plurality of LEDs when viewed from top down or bottom up. The plurality of second lenses may overlap the transparent region of the display when viewed from top down or bottom up.

Another general aspect includes a display. The display may be formed using any of the methods described above for forming a display. For example, a display may include a plurality of LEDs on a substrate. Each pixel of the display may comprise one or more LEDs of the plurality of LEDs and a transparent region of the display, where the transparent region transmits light external to the display through the display. As another example, a display may include a first layer comprising a plurality of first LEDs and a second layer comprising a plurality of second LEDs. The plurality of first LEDs emit light of a first color. The plurality of second LEDs emit light of a second color different than the first color. Each pixel of the display comprises a corresponding first LED from the first layer and a corresponding second LED from the second layer. A transparent region between pixels transmits light external to the display through the display. The display may include a third layer comprising a plurality of third LEDs, where the plurality of third LEDs emit light of a third color different than the first color and the second color. Each pixel of the display may further comprise a corresponding third LED from the third layer.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1F schematically illustrate examples of a display device, according to some embodiments;

FIGS. 2A-2G schematically illustrate examples of a display device, according to some embodiments;

FIG. 3 schematically illustrates an example of a display device, according to some embodiments;

FIG. 4 schematically illustrates examples of pixel configurations of a display device, according to some embodiments;

FIG. 5 schematically illustrates an example of a pixel configuration with a lens of a display device, according to some embodiments;

FIG. 6A schematically illustrate example views of a display of an augmented reality display device, according to some embodiments;

FIGS. 6B-6C schematically illustrate an example method for forming a portion of a display, according to some embodiments;

FIGS. 7A-7B schematically illustrates example views of a pixel configuration in a display device, according to some embodiments;

FIGS. 8A-8B schematically illustrate hybrid bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for methods to form a display or an augmented reality device with glasses and a display in a viewing area of the glasses that enable light to pass through between pixels of the display for a viewer to see a real life image or surrounding. Advantageously, the embodiments may remove use of an assembly for optical delivery of an image of a display to a viewing area, and use a high efficiency, high-brightness display in the viewing area of the user. The display may be an LED display (e.g., micro LED display) that provides high brightness. An active area of the display including the LEDs (e.g., portion of the display that may actively emit light generated from the LEDs) may be opaque (e.g. opaque back plane) and block or prevent external light from passing through the display, while at least a portion of an inactive area of the display may be transparent and enable external light to pass through the display.

For an augmented reality device, it may be relevant to have glasses with a display and ability for light to pass through to see the external world. To do so, an augmented reality device may have an assembly of lenses, mirrors, and waveguides to deliver an image from a display to a viewing area on the glasses. However, use of the assembly increases complexity of an augmented reality device. Use of a different approach, which places a transparent OLED or LCD display on the viewing area on the glasses may have limited brightness and pixel size limitations.

An augmented reality device may comprise glasses that have a display and ability for light to pass through to see the external world. An augmented reality device may have an assembly of lenses, mirrors, and waveguides that deliver an image from a display to a viewing area on the glasses in front of the eye (e.g., typically about 10-20 cm). The assembly may be optimized to provide minimal image distortion and minimal loss of brightness from display to delivery to the viewing area, and to enable an adequate amount of light to pass through from the real world to see a real life image or surrounding. The use of the assembly increases a complexity of an augmented reality device comprising glasses and a display. The assembly may include a waveguide which may limit a viewing angle (e.g., around 55°), limit the brightness, and/or reduce efficiency of the display (e.g., diffracted light in the waveguide may escape). In some approaches, instead of an assembly, an augmented reality device may comprise a transparent organic light emitting diode (OLED, LCD, etc.) display on the viewing area on the glasses. However, the transparent OLED or LCD display may have limited brightness and pixel size limitations.

Embodiments of this disclosure may enable a display or an augmented reality device using glasses and a display in a viewing area of the glasses that enable light to pass through between pixels of the display to see a real life image or surrounding. Advantageously, the embodiments may remove use of an assembly for optical delivery of an image of a display to a viewing area, and use a high efficiency, high-brightness display in the viewing area of the user.

As described below, semiconductor substrates, display substrates, or micro-LED display substrates herein generally have a “device side,” e.g., the side on which semiconductor device elements are fabricated, such as transistors, resistors, capacitors, micro-LEDs, driver circuits, and interconnects, and a “backside” that is opposite the device side. The term “active side” or “display surface” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

In some embodiments, the term “substrate” herein refers to an element of a device made of silicon or other semiconductor materials. Alternatively, or additionally, the substrate includes other semiconductor materials such as germanium, gallium arsenic, or other suitable semiconductor materials. In some embodiments, substrate may further include other features such as various doped regions, a buried layer, and/or an epitaxy layer. Moreover, in some embodiments, substrate is made of an alloy semiconductor such as silicon germanium, silicon germanium carbide, gallium arsenic phosphide, or gallium indium phosphide. Furthermore, the substrate may be a semiconductor on insulator such as silicon on insulator (SOI) or silicon on sapphire.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material.

Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

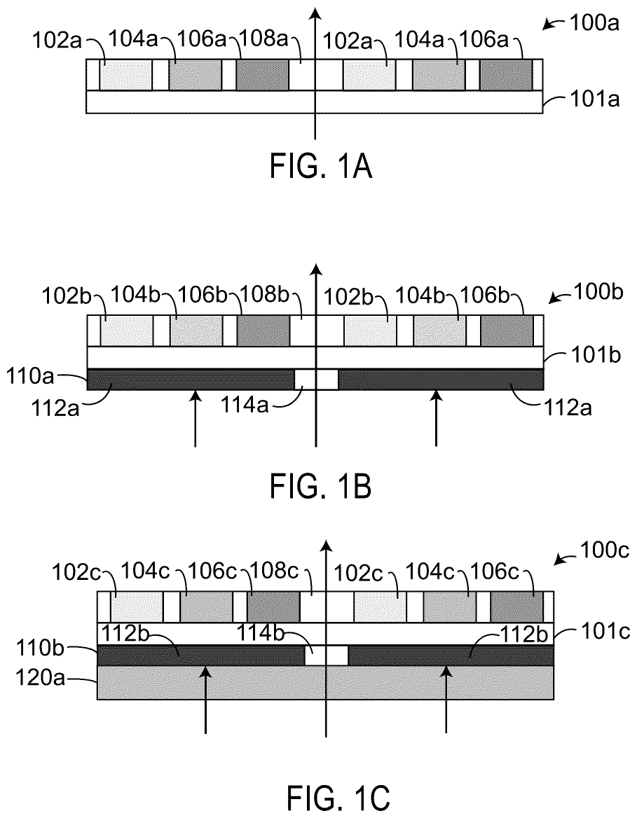

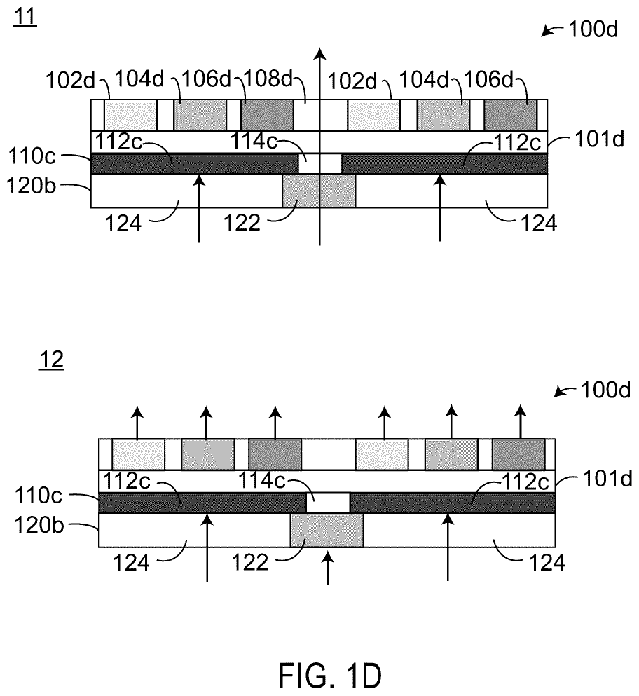

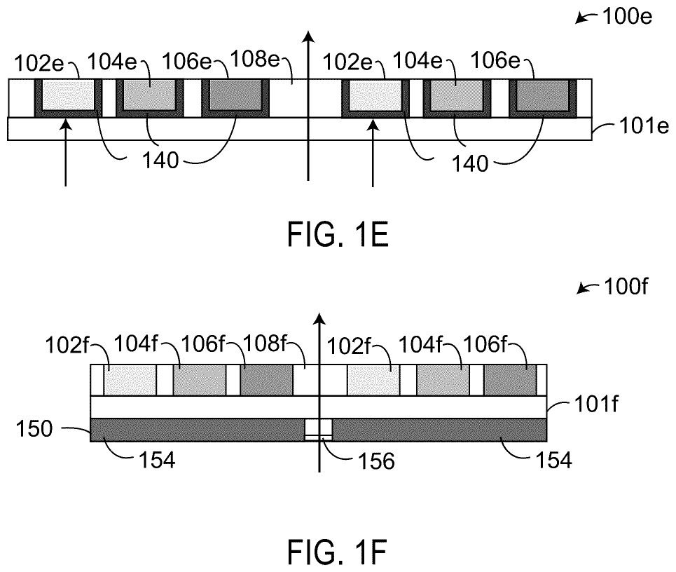

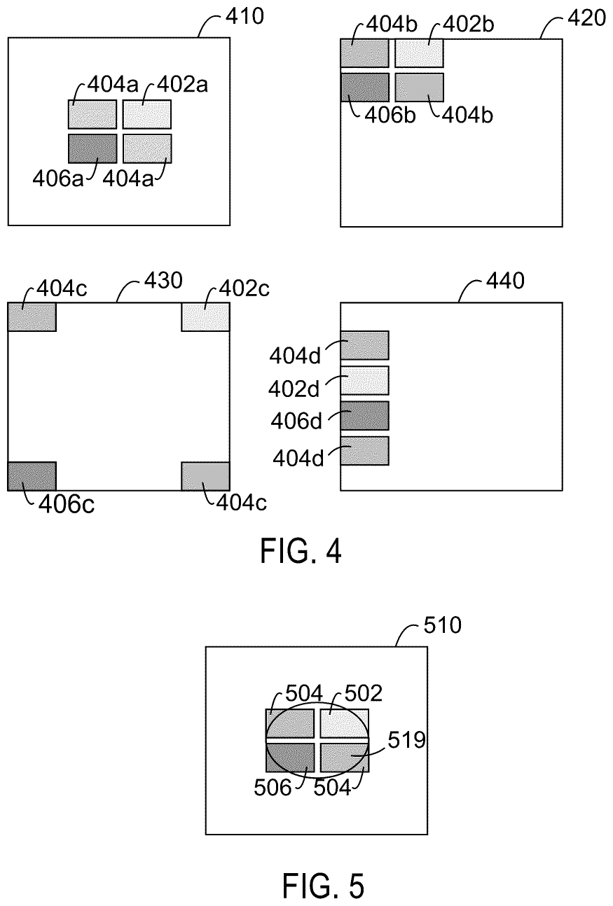

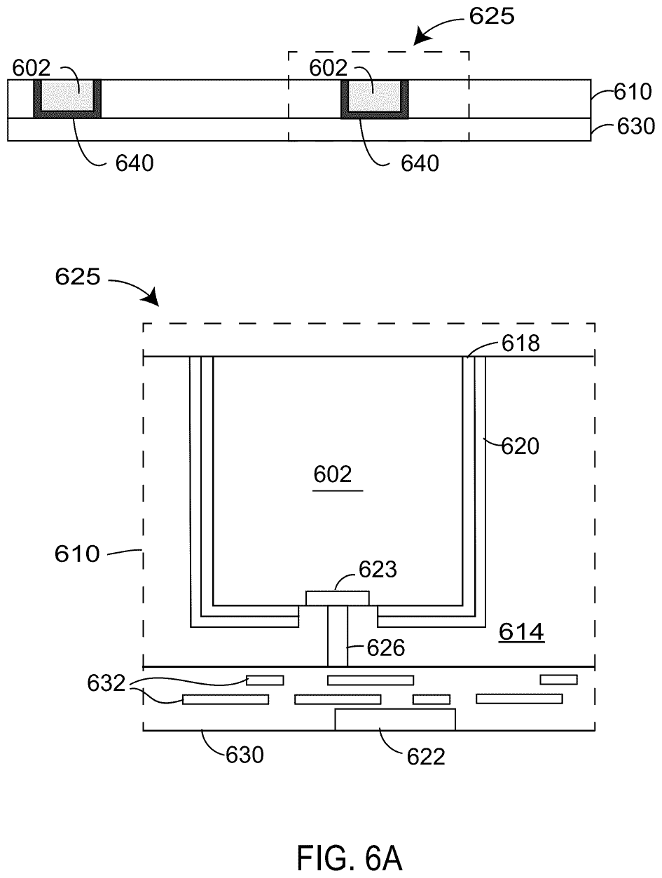

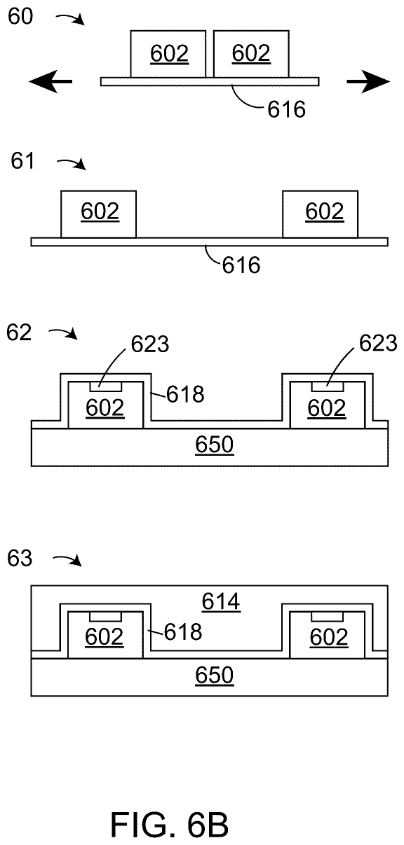

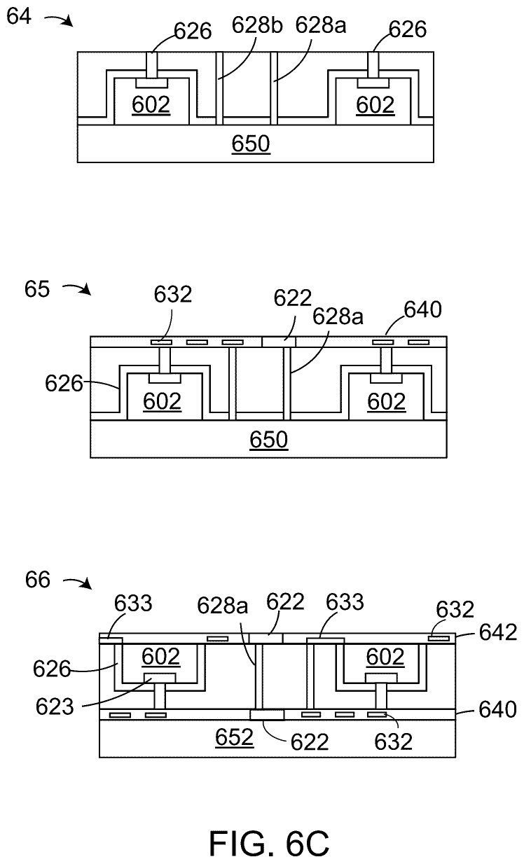

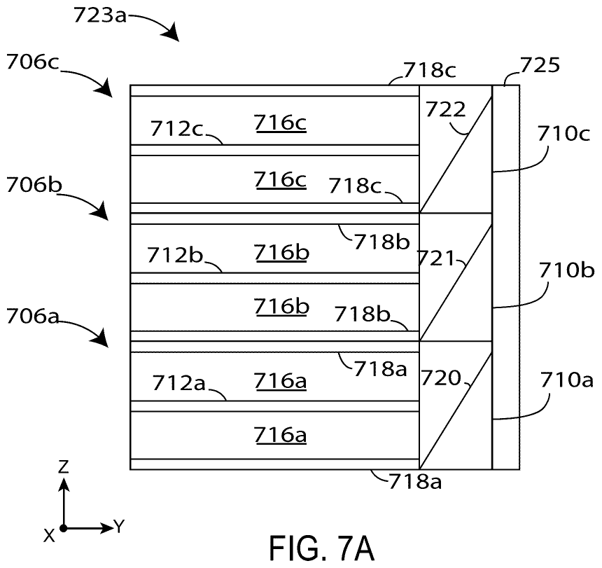

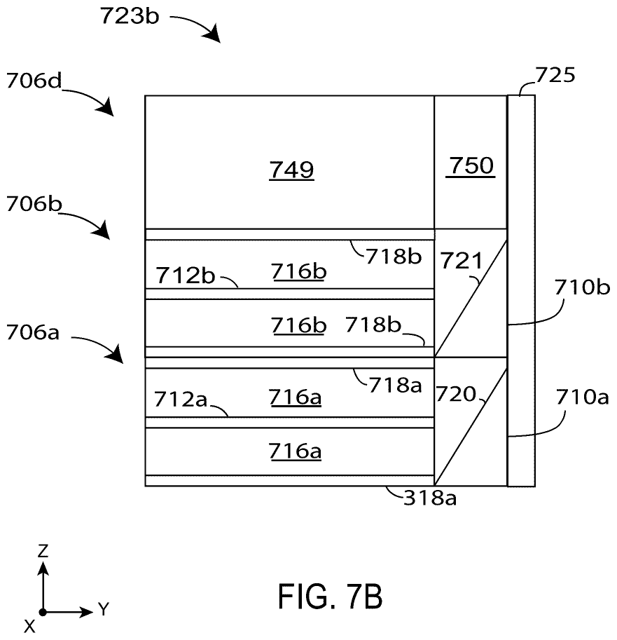

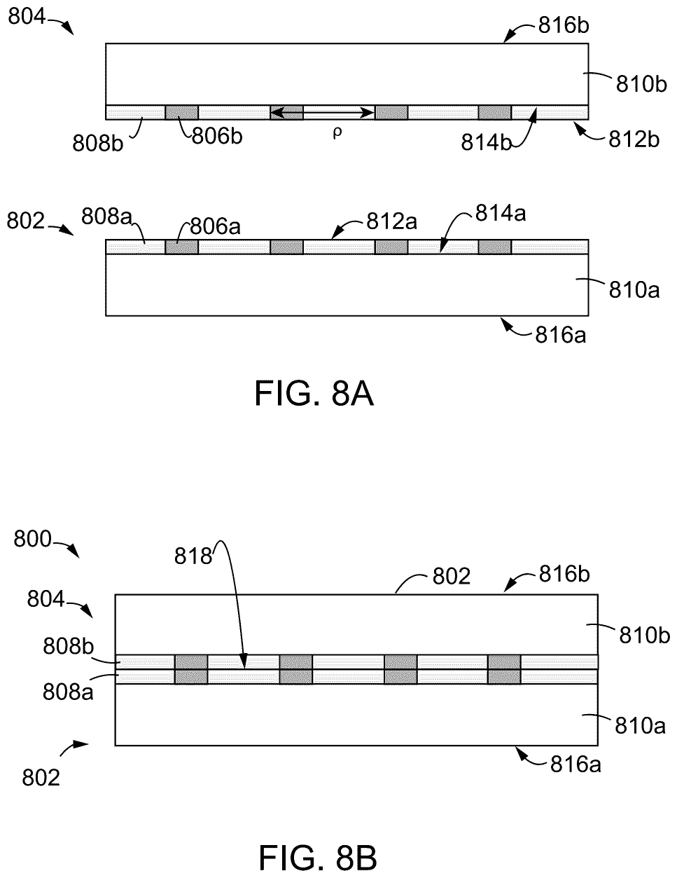

FIGS. 1A-1F, 2A-2G, and 3 schematically illustrate various embodiments of a display. In some embodiments, the display is a display of an augmented reality display device. In some embodiments, a display (e.g., displays 100a-f, displays 200a-g, display 300, or any suitable display described throughout the present disclosure) may be a microLED display and comprise microLEDs, with sizes equal to or less than about 100 microns, 50 microns, or 5 microns. FIGS. 4 and 5 show pixel configurations that may be applied to a display (e.g., any suitable display described throughout the present disclosure). FIG. 6A shows details of a substrate with LEDs that may be applied to a display (e.g., displays 100a-f, displays 200a-g, display 300, or any suitable display described throughout the present disclosure). FIGS. 7A-7B show details of a display with edge emitting LEDs (e.g., display 300 or any suitable display described throughout the present disclosure, such as those shown in FIG. 3). FIGS. 8A-8B illustrate a hybrid bonding method for bonding substrates (e.g., substrates comprising LEDs to substrates comprising LEDs, substrates comprising LEDs to substrates comprising control devices and/or LEDs).

FIGS. 1A-1F, 2A-2G, and 3 schematically illustrate embodiments of a display or an augmented reality display device where a viewpoint of a user is shown at the top portion of the display. The display may be an LED display (e.g., micro-LED display). A micro-LED display may have pixels of less than about 100 microns, less than about 50 microns in size, less than about 10 microns in size, or less than about 5 microns in size. A pixel may comprise a plurality of sub-pixels. For example, a pixel may comprise a first sub-pixel, and second sub-pixel, and a third sub-pixel. Each sub-pixel may comprise an LED that emits light of a particular color. In the examples shown in FIGS. 1A-1F, 2A-2G, and 3, two pixels with three sub-pixels are shown for illustrative purposes. However, a display may have any suitable number of pixels (e.g., two or more, thousands of pixels, or millions of pixels) and sub-pixels (e.g., one, two, three or more). In some embodiments, each sub-pixel may be any suitable shape (e.g., rectangle, etc.) and color (e.g., emits light of any suitable color, red, green, blue, cyan, magenta, white, etc.). In certain embodiments, advancements in color conversion layers (e.g. colored phosphors, quantum dot layers, etc.) may permit the addition of a fourth color, like a green variant or cyan, to enhance the color gamut. As another example, FIGS. 4-5 show a pixel with four sub-pixels, where one of the colors of the sub-pixels is repeated (e.g., green, red, blue, and green).

In some embodiments, as shown in FIGS. 1A-1F, a display may comprise plurality of sub-pixels that are adjacent to each other and non-overlapping in a vertical direction (e.g., in a top-down view). For example, different colored LEDs may be fabricated on different wafers (e.g., red LED wafer, green LED wafer, blue LED wafer), singulated (e.g., diced) into individual LEDs (e.g., red LEDs, green LEDs, and blue LEDs), and then transferred (e.g., picked and placed) onto a display backplane (e.g., transistor matrix) to form a display. Transferring LEDs of one color may be performed for an entire wafer or large portions of a wafer by using similar transfer techniques such as those described at FIGS. 6B-6C.

FIG. 1A shows a display 100a. Each pixel of display 100a comprises three sub-pixels (sub-pixel 102a, sub-pixel 104a, and sub-pixel 106a) comprising different colored LEDs. For example, sub-pixel 102a may comprise a red LED, sub-pixel 104a may comprise a green LED, and sub-pixel 106a may comprise a blue LED. Each LED may be an LED (e.g., a micro-LED) which was singulated from different wafers and transferred onto a substrate 101a. The regions between adjacent LEDs may be filled with a dielectric layer (e.g., reconstitution dielectric) so that the LEDs are embedded in a dielectric layer. In some embodiments, a dielectric layer comprises Si oxide material. The dielectric layer may be transparent to red, green, and blue wavelengths of light. The dielectric layer may cover a top surface of the LEDs. In some embodiments a top surface of the dielectric layer may be planarized. The substrate 101a may comprise a transistor matrix for controlling individual pixels and/or subpixels. The substrate 101a may comprise a processor (e.g., read out integrated circuit or ROIC) or controller that the LEDs may be communicatively coupled to (e.g., bonded to via bond pads of the processor and LEDs). In some embodiments, the substrate 101a may comprise an interconnect layer (e.g., redistribution layer or RDL). The LEDs may have electrodes that are electrically coupled to bond pads via interconnects of an interconnect layer. The interconnect layer comprising bond pads embedded in a dielectric layer may be hybrid bonded to bond pads of a processor or controller embedded in a dielectric layer. The display 100a comprises a transparent region 108a between pixels in which light can be transmitted through the display 100a. Additional detail of a reconstituted substrate of LEDs can be found in FIGS. 6A-6C.

FIG. 1B shows a display 100b that is similar to display 100a of FIG. 1A, except the display 100b includes a passive light blocker layer 110a. For example, substrate 101b, sub-pixels 102b, 104b, and 106b, and transparent region 108b of FIG. 1B correspond to (e.g., are the same or similar to) substrate 101a, sub-pixels 102a, 104a, and 106a, and transparent region 108a of FIG. 1A. The passive light blocker layer 110a comprises a plurality of passive light blockers 112a and transparent regions 114a (a single transparent region 114a is shown in FIG. 1A for simplicity). Each passive light blocker 112a may overlap vertically with an active area of each pixel (e.g., light-emitting area corresponding to sub-pixels 102b, 104b, and 106b) and an inactive area (e.g., non-emissive portion) between pixels (e.g., regions between sub-pixels 102b and 104b, and 104b and 106b or between LEDs that does not emit light). Transparent region 114a separates passive light blockers 112a of adjacent pixels, and may overlap vertically with a transparent region 108b of each pixel (e.g., non-active, transparent area of each pixel adjacent to sub-pixels 102b, 104b, and 106b that does not emit light). In some embodiments, transparent regions 114a may comprise an air gap. For example, the passive light blocker layer 110a may comprise a patterned opaque layer (e.g., comprising a reflective material, metal layer) that is coated on a surface of the substrate 101b, and each patterned opaque layer corresponds to a passive light blocker 112a with air gaps corresponding to the transparent regions 114a between the adjacent patterned opaque layers (passive light blockers 112a). In some embodiments, the transparent regions 114a may be a transparent material layer (e.g., transparent dielectric layer) that the passive light blockers 112a are dispersed in. When subpixels 102b, 104b, 106b (e.g., LEDs) are off or not emitting light, the light blockers 112a may block any other light (e.g., stray light, transmissive light, etc.) to enable a very high contrast black and white (e.g., a high contrast ratio of brightness when LEDs are on vs. when LEDs are off). When an LED is on or emitting light, the LED has its brightness. When LEDs are off or are not emitting light, the light blockers 112a may block any other stray or transmissive light to make it true black, and improving color contrast.

FIG. 1C shows a display 100c that is similar to display 100b of FIG. 1B, except it includes a controllable light blocker layer 120a. For example, substrate 101c, sub-pixels 102c, 104c, and 106c, transparent region 108c, and passive light blocker layer 110b comprising passive light blockers 112b and transparent region 114b of FIG. 1C correspond to (e.g., are the same or similar to) substrate 101b, sub-pixels 102b, 104b, and 106b, transparent region 108b, and passive light blocker layer 110a comprising passive light blockers 112a and transparent regions 114a of FIG. 1B. The controllable light blocker layer 120a may comprise a controllable light blocker material (e.g., liquid crystal material) that can be used block or transmit light in a transparent region between two pixels (e.g., corresponding to transparent region 108c and 114b). For example, the controllable light blocker layer 120a may be used to block light from transmitting through the display when the sub-pixels 102c, 104c, and 106c emit light, and may be used to transmit light through the display when the sub-pixels 102c, 104c, and 106c do not emit light.

In some embodiments, the controllable light blocker material may be a continuous layer and cover an entire pixel area (e.g., both active and inactive areas) of the display 100b. For example liquid crystal material may be dispersed between electrodes. One or more electrodes may be patterned, so that an electrode pair and corresponding liquid crystal material (e.g., liquid crystal material between the electrode pair) corresponds to a pixel or any suitable number of pixels (1, 2 or more pixels). In some embodiments, an electrode pair comprises a first electrode that is patterned (e.g., corresponding to one pixel or 2 or more pixels) and a second electrode that is not patterned (e.g., a continuous common electrode for the controllable light blocker layer 120a). In some embodiments, a first and a second electrode may be patterned. In some embodiments, a light blocker may refer to the patterned electrode(s) and corresponding liquid crystal material between the patterned electrode(s) (e.g., overlapping region of the patterned electrode(s)), and a display comprises a plurality of light blockers (e.g., having a same number of light blockers as overlapping regions of the patterned electrode(s)).

In some embodiments, applying a bias to the electrodes may order the liquid crystal material in a state that enables light to pass through the liquid crystal material, and removing a bias to the electrodes may return the liquid crystal material to state that prevents light from passing through. In some other embodiments, not applying a bias may enable light to pass through the liquid crystal material, and applying a bias to the electrodes may prevent light from passing through.

In some embodiments, a controllable light blocker may correspond to an area between two pixels, as shown in FIG. 1C. Each controllable light blocker layer 120a may overlap with a region 114b separating a passive light blocker 112b of adjacent pixels. In some embodiments, a controllable light blocker 120a corresponds to one region 114b separating adjacent passive light blockers 112b. In some embodiments, a controllable light blocker 120a corresponds to multiple regions 114b separating passive light blockers 112b.

In some embodiments, a controllable light blocker may correspond to a single pixel. For example, from a top view of a pixel layout in FIG. 4, a controllable light blocker may cover areas in non-active areas of a pixel that are transparent (e.g., portions that do not emit light and are outside LEDs 402a-d, 404a-2, 406a-d)).

In some embodiments, the controllable light blocker layer 120a may be used without the passive light blocker layer 110b of FIG. 1C. For example, instead of the controllable light blocker layer 120a being adjacent to the passive light blocker layer 110b, the controllable light blocker layer 120a is adjacent to substrate 101c.

FIG. 1D shows a display 100d that is similar to display 100c of FIG. 1C, except it includes a controllable light blocker layer 120b that is patterned instead of a continuous controllable light blocker layer 120a. For example, substrate 101d, sub-pixels 102d, 104d, and 106d, transparent region 108d, and passive light blocker layer 110c comprising passive light blockers 112c and transparent regions 114c of FIG. 1D correspond to (e.g., are the same or similar to) substrate 101c, sub-pixels 102c, 104c, and 106c, transparent region 108c, and passive light blocker layer 110b comprising passive light blockers 112b and transparent regions 114b of FIG. 1C. The controllable light blocker layer 120b is patterned, and may comprise one or more light blockers and one or more regions adjacent to the light blockers (shown here in FIG. 1D as a single light blocker 122 and two regions 124 adjacent to the light blocker 122). In the regions 124, one or more electrodes and/or light blocker material may not be present. For example, a light blocker 122 comprising liquid crystal material and corresponding electrodes may be patterned to cover a region in between pixels. In some embodiments, liquid crystal material may be continuous (e.g., across a pixel area and/or display area), and one or more electrodes may be patterned (e.g., corresponding to the region corresponding to light blocker 122).

In some embodiments, the controllable light blocker layer 120b may be used without the passive light blocker layer 110c of FIG. 1D. For example, instead of the controllable light blocker layer 120b being adjacent to the passive light blocker layer 110c, the controllable light blocker layer 120a is adjacent to substrate 101d.

At block 11, an example is shown where each sub-pixel is not emitting light and the controllable light blocker 122 enables light to pass through the display 100d. For example, electrodes of the controllable light blocker 122 may be biased (e.g., voltage applied across the electrodes), and liquid crystal material of the controllable light blocker 122 may enable light to pass through the display 100d.

At block 12, an example is shown where each sub-pixel is emitting light, and the controllable light blocker 122 prevents light to pass through the display 100d. For example, no bias may be applied to electrodes of the controllable light blocker 122, and liquid crystal material of the controllable light blocker 122 may prevent light from passing through the display 100d.

FIG. 1E shows a display 100e that is similar to the display 100a of FIG. 1A, except it comprises passive light blockers 140 for each sub-pixel 102e, 104e, and 106e of display 100e. For example, the substrate 101e, sub-pixels 102e, 104e, and 106e, and transparent region 108e correspond to substrate 101a, sub-pixels 102a, 104a, and 106a, and transparent region 108a of FIG. 1A. The passive light blockers 140 may comprise a material that reflects light. For example, the passive light blockers 140 for each sub-pixel may comprise a metal film on the bottom and side surfaces of each LED. The passive light blockers 140 may be combined with any of the embodiments described in relation to FIGS. 1B-1E.

FIG. 1F shows a display 100f that is similar to the display 100b of FIG. 1B, except it includes a reconstituted substrate layer 150 to block light instead of a passive light blocker layer 110a of FIG. 1B, and may include transparent wiring 156 that overlaps vertically in transparent regions between pixels. For example, substrate 101f, sub-pixels 102f, 104f, and 106f, and transparent region 108f correspond to substrate 101b, sub-pixels 102b, 104b, and 106b, and transparent region 108b of FIG. 1B. The reconstituted substrate layer 150 may comprise singulated chips 154 and transparent wiring 156. The singulated chips 154 may comprise a processor or controller or other components to operate or control LEDs of the display 100f. Transparent wiring 156 may be formed in portions of the display 100f that overlaps vertically in transparent regions 108f between the pixels. The transparent wiring 156 may comprise transparent conductive materials (e.g., transparent conductive oxide materials). In some embodiments, the reconstituted substrate layer 150 may be used in addition to the passive light blocker layer 110a of FIG. 1B.

In some embodiments, the singulated chips 154 may correspond to a passive light blocker (e.g., blocks light from being transmitted through the display), and a region between adjacent pixels may comprise transparent wiring 156. For example, the singulated chips 154 may comprise a diced wafer (e.g., silicon) for each pixel, and areas between each set of pixels may comprise transparent wiring 156.

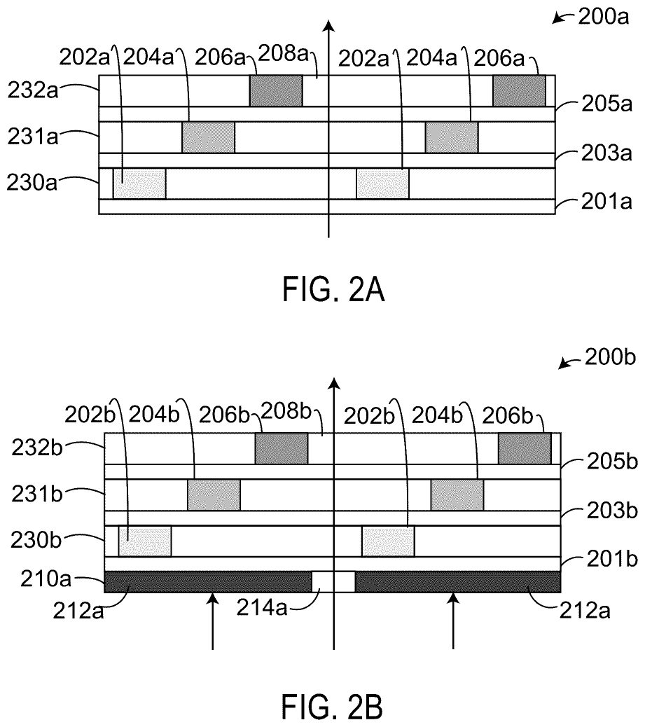

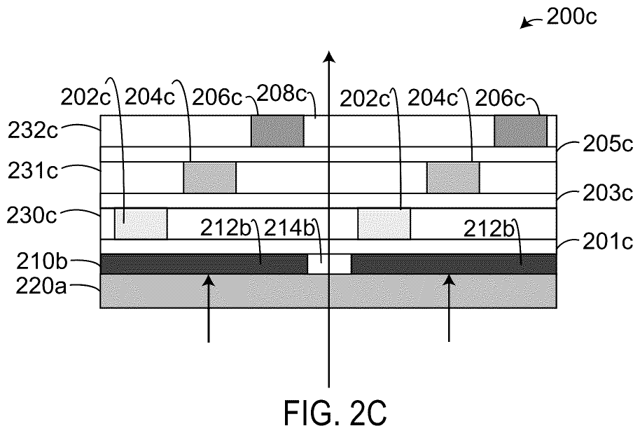

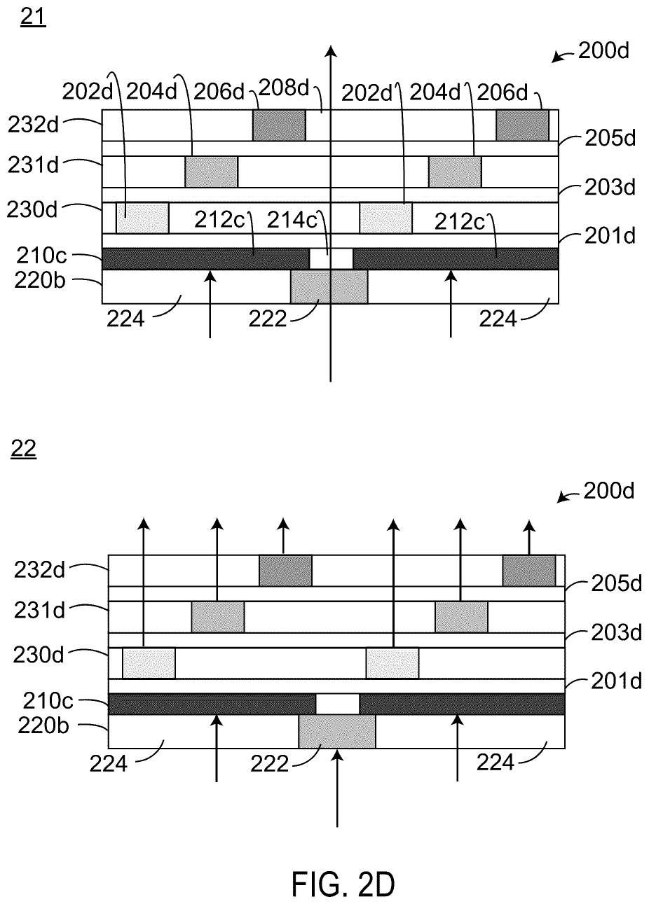

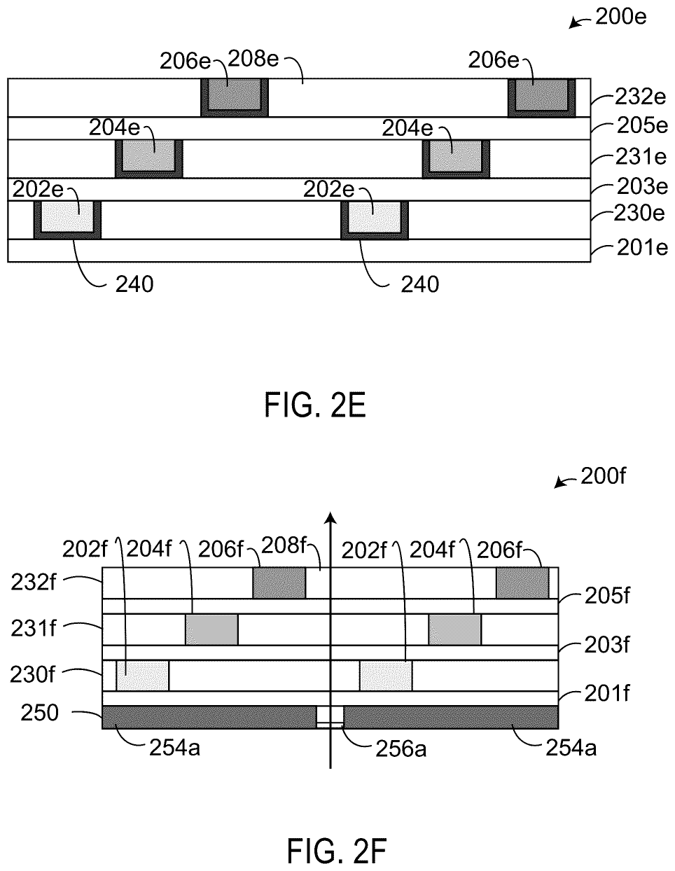

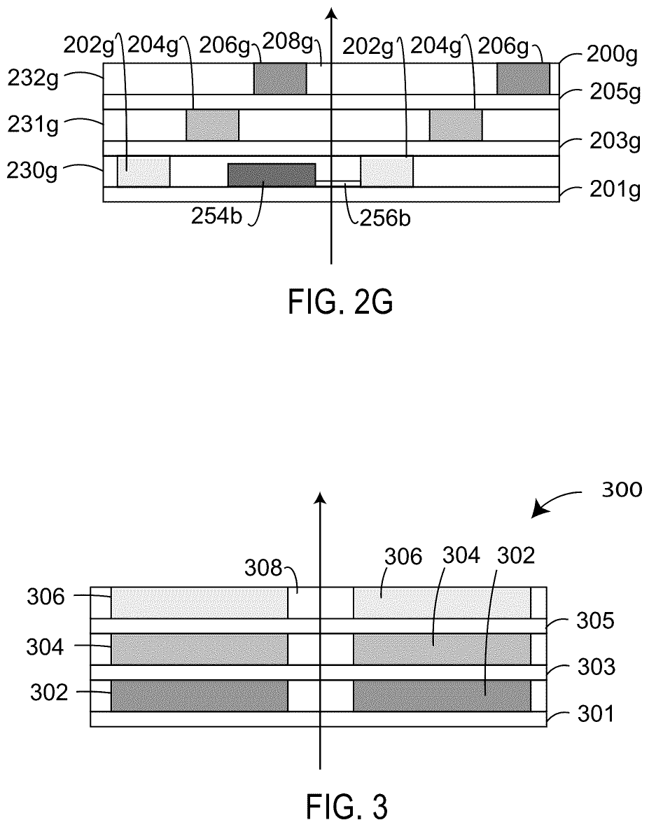

In some embodiments, as shown in FIGS. 2A-2G and 3, a display may comprise a plurality of sub-pixels that are stacked. The stacked plurality of sub-pixels may not overlap in a vertical direction (e.g., FIGS. 2A-2G). The stacked plurality of sub-pixels may overlap in a vertical direction (e.g., FIG. 3). For a stacked display, each layer may comprise different colored LEDs. In some embodiments, the stacked display may use any suitable combination of colors or any suitable stacked order of colors. For example, a first layer may comprise LEDs that emit light of a first color, and a second layer may comprise LEDs that emit light of a second color, and a third layer may comprise LEDs that emit light of a third color. The substrate for each stacked layer may correspond to substrates 101a-f of FIGS. 1A-1F, except that each substrate may comprise relevant circuitry for a corresponding LED of one color in a layer instead of a single substrate including relevant circuitry for LEDs of different colors. In some embodiments, each substrate may comprise interconnects and vias to connect LEDs of each substrate to relevant circuitry to an underlying layer. In some embodiments, each layer of LEDs or reconstituted substrate may be formed using a similar method such as described in FIGS. 6B-6C.

FIG. 2A shows a display 200a with three sub-pixels (e.g., sub-pixel 202a, sub-pixel 204a, and sub-pixel 206a). Each sub-pixel 202a, 204a, and 206a may be different colored LED in a corresponding layer 230a, 231a, 232a, that does not overlap in a vertical direction. For example, sub-pixel 202a may be a red LED, sub-pixel 204a may be a green LED, and sub-pixel 206a may be a blue LED, and each LED may be positioned to be offset from each other so as not to overlap in a vertical direction. Each LED may be a micro-LED which was singulated from different wafers and transferred to a corresponding substrate. For example, sub-pixels 202a that may be red LEDs may be placed on a substrate 201a, sub-pixels 204a that may be green LEDs may be placed on a substrate 203a, and sub-pixels 206a may be placed on substrate 205a. The substrate 201a, 203a, and 205a may each be a reconstituted LED wafer. Each reconstituted LED wafer may comprise at least one of bond pads, an interconnect layer (e.g., redistribution layer or RDL), and vias. At least one of the substrates 201a, 203a, and 205a may comprise a processor (e.g., ROIC) or controller that the LEDs are communicatively coupled to (e.g., bonded to via bond pads of the processor and LEDs). In some embodiments, vias may extend through a layer 230b, 231b, and 232b to electrically connect a corresponding LED to a processor or controller. In some embodiments, the interconnects and vias in the interconnect layer may be transparent (e.g., comprise a transparent conductive oxide material) or opaque (e.g., comprise a metal material). In some embodiments, a dielectric layer may cover the top surface of the LEDs in each layer and be planarized. In some embodiments, a dielectric layer comprises Si oxide material. The dielectric layer may be transparent to red, green, and blue wavelengths of light. In some embodiments, a first layer 230b on first substrate 201b, a second layer 231b on second substrate 203b, and a third layer 232b on third substrate 205b may be bonded to each other. The display 200a has a transparent region 208a between pixels in which light can be transmitted through the display 200a.

FIG. 2B shows a display 200b that is similar to display 200a of FIG. 2A, except it includes a passive light blocker layer 210a. For example, substrates 201b, 203b, and 205b, sub-pixel layers 230b, 231b, and 232b, sub-pixels 202b, 204b, and 206b, and transparent region 208b of FIG. 2B correspond to substrates 201a, 203a, and 205a, sub-pixel layers 230a, 231a, and 232a, sub-pixels 202a, 204a, and 206a, and transparent region 208a of FIG. 2A. Passive light blocker layer 210a, passive light blocker 212a, and transparent region 214a of FIG. 2B may be similar to passive light blocker layer 110a, passive light blocker 112a, and transparent region 114a of FIG. 1B.

FIG. 2C shows a display 200c that is similar to display 200b of FIG. 2B, except it includes a controllable light blocker 220a. For example, substrates 201c, 203c, and 205c, sub-pixel layers 230c, 231c, and 232c, sub-pixels 202c, 204c, and 206c, passive light blocker layer 210b comprising light blockers 212b and transparent region 214b, and transparent region 208c of FIG. 2C correspond to substrates 201b, 203b, and 205b, sub-pixel layers 230b, 231b, and 232b, sub-pixels 202b, 204b, and 206b, passive light blocker layer 210a comprising light blockers 212a and transparent region 214a, and transparent region 208b of FIG. 2B. Controllable light blocker layer 220a may be similar to controllable light blocker layer 120a of FIG. 1C.

In some embodiments, the controllable light blocker layer 220a may be used without the passive light blocker layer 210b of FIG. 2C. For example, instead of the controllable light blocker layer 220a being adjacent to the passive light blocker layer 210b, the controllable light blocker layer 220a is adjacent to substrate 201c.

FIG. 2D shows a display 200d that is similar to display 200c of FIG. 2C, except it includes a controllable light blocker layer 220b that is patterned. For example, substrates 201d, 203d, and 205d, sub-pixel layers 230d, 231d, and 232d, sub-pixels 202d, 204d, and 206d, passive light blocker layer 210c comprising light blockers 212c and transparent region 214c, and transparent region 208d of FIG. 2D correspond to (e.g., are the same or similar to) substrates 201c, 203c, and 205c, sub-pixel layers 230c, 231c, and 232c, sub-pixels 202c, 204c, and 206c, passive light blocker layer 210b comprising light blockers 212b and transparent region 214b, and transparent region 208c of FIG. 2C. The controllable light blocker layer 220b is patterned, and comprises one or more light blockers 222 and other regions 224 (FIG. 2D shows a single light blocker 222 and two other regions 224 for purposes of illustration). For example, a light blocker 222 comprising liquid crystal material and corresponding electrodes may be patterned to cover a region in between pixels.

At block 21, an example is shown where each sub-pixel is not emitting light, and the controllable light blocker 222 enables light to pass through the display 200d. For example, electrodes of the controllable light blocker 222 may be biased (e.g., voltage applied across the electrodes), and liquid crystal material of the controllable light blocker 222 may enable light to pass through the display 200d.

At block 22, an example is shown where each sub-pixel is emitting light, and the controllable light blocker 222 prevents light to pass through the display 200d. For example, no bias may be applied to electrodes of the controllable light blocker 222, and liquid crystal material of the controllable light blocker 222 may prevent light from passing through the display 200d.

FIG. 2E shows a display 200e that is similar to the display 200a of FIG. 2A, except it comprises passive light blockers 240 for each sub-pixel 202e, 204e, and 206e of display 200e. For example, substrates 201e, 203e, and 205e, sub-pixel layers 230e, 231e, and 232e, sub-pixels 202e, 204e, and 206e, and transparent region 208e of FIG. 2E correspond to substrates 201a, 203a, and 205a, sub-pixel layers 230a, 231a, and 232a, sub-pixels 202a, 204a, and 206a, and transparent region 208a of FIG. 2A. The passive light blockers 240 of FIG. 2E may be similar to the passive light blockers 140 of FIG. 1E. The passive light blockers 240 may comprise a reflective material (e.g., metal material). The passive light blockers 240 for each sub-pixel may comprise a metal film on the bottom and side surfaces of each LED. The passive light blockers 240 may be combined with any of the embodiments described in relation to FIGS. 2B-2D, 2F and 2G.

FIG. 2F shows a display 200f that is similar to the display 200b of FIG. 2B, except it uses a reconstituted substrate layer 250 to block light instead of a passive light blocker layer 210a of FIG. 2B, and may include transparent wiring 256a that overlaps vertically in transparent regions 208f between pixels. For example, substrates 201f, 203f, and 205f, sub-pixel layers 230f, 231f, and 232f, sub-pixels 202f, 204f, and 206f, and transparent region 208f of FIG. 2F correspond to substrates 201b, 203b, and 205b, sub-pixel layers 230b, 231b, and 232b, sub-pixels 202b, 204b, and 206b, and transparent region 208b of FIG. 2B. The singulated chip 254a may comprise a processor or controller or other components to operate or control LEDs of the display 200f. In some embodiments, a singulated chip 254a may correspond to each pixel of the display 200f In other embodiments, a singulated chip 254a may correspond to two or more pixels (e.g., hundreds of pixels, a row or column of pixels) of the display 200f For example, there may be a controller to provide signals to turn on or off a row or a column of pixels of the display 200f Transparent wiring 256a may be formed in portions of the display that overlaps vertically in transparent regions 208f between the pixels. The transparent wiring 156 may comprise transparent conductive materials (e.g., transparent conductive oxide materials). In some embodiments, a reconstituted substrate 224a may comprise a diced silicon wafer that prevents light to pass through in between adjacent pixels.

FIG. 2G shows a display 200g that is similar to the display 200f of FIG. 2F, except it uses a singulated chip 254b and transparent wiring 256b in a sub-pixel layer instead of in a separate layer 250 of FIG. 2F. For example, substrates 201g, 203g, and 205g, sub-pixel layers 230g, 231g, and 232g, sub-pixels 202g, 204g, and 206g, and transparent region 208g of FIG. 2G correspond to substrates 201f, 203f, and 205f, sub-pixel layers 230f, 231f, and 232f, sub-pixels 202f, 204f, and 206f, and transparent region 208f of FIG. 2F The singulated chips 254b may be similar to the singulated chips 254a of FIG. 2F, except that the location vertically may be in a sub-pixel layer (e.g., sub-pixel layer 230g) and it may cover a region between sub-pixels (e.g., between sub-pixels 204g and 206g) instead of multiple regions between sub-pixels (e.g., between sub-pixels 202f and 204f and between sub-pixels 204f and 206f). Transparent wiring 256b may be similar to transparent wiring 256a of FIG. 2F, except that it may be formed in a sub-pixel layer (e.g., sub-pixel layer 230g). In some embodiments, the singulated chips 254b and transparent wiring 256b may be formed in any suitable sub-pixel layer (e.g., sub-pixel layer 231g instead of 230g).

FIG. 3 shows a display 300 with sub-pixels 302, 304, and 306 and a transparent region 308 between pixels in which external light can be transmitted through the display 300. The display 300 may be a light emitting diode (LED) display. For example, display 300 may be a stacked LED display with sub-pixels that overlap in a vertical direction, and sub-pixels 302, 304 and 306 may be different colored LEDs. For example, sub-pixel 302 may be a blue LED, sub-pixel 304 may be a green LED, and sub-pixel 306 may be a red LED. The different colored LEDs may be fabricated on different substrates 301, 303, and 305, and bonded to each other using a hybrid bonding process. For example, different colored LEDs may be singulated from a corresponding wafer (e.g., red LED wafer, green LED wafer, blue LED wafer) and transferred to different substrates 301, 303, and 305. Each substrate 301, 303, and 305 may be similar to substrates 201a, 203a, and 205a of FIG. 2A. In some embodiments, the display 300 may be used with features of the embodiments described in relation to FIG. 2B (e.g., passive light blocker 210a), FIGS. 2C and 2D (e.g., controllable light blocker 220a, 220b), and FIG. 2E (e.g., passive light blocker 240), FIG. 2F (e.g., reconstituted substrate layer 250), and FIG. 2G (e.g., a singulated chip 254b and transparent wiring 256b in a sub-pixel layer).

In some embodiments, the display 300 may comprise edge-emitting LEDs. For example, an LED may comprise a stack of LED material layers, and light may be output from an edge of the stack of layers (e.g., edge of an active layer) instead of a direction normal to the stack of layers (e.g., surface of an active layer, as in a surface-emitting LED). A display 300 may comprise mirrors corresponding to and adjacent to each edge-emitting LED to direct the edge-emitted light to exit the display 300 in a direction normal to a surface of the display 300. For example, a mirror may be positioned in a region of the display corresponding to the transparent region 308 between pixels, adjacent to a corresponding edge-emitting LED. The mirror may be positioned at an angle to reflect light generated from the edge-emitting LED to exit a surface of the display 300 to a viewpoint of the user at the top of the display.

In some embodiments, one or more mirrors may be dichroic mirrors or reflecting cubes with appropriate dichroic coatings. A dichroic mirror may be a mirror with different reflection or transmission properties at two different wavelength ranges or regions. For example, sub-pixel 302 (e.g., blue LED) may have a corresponding adjacent mirror (e.g., tuned to reflect blue light) in a same layer and in a location corresponding to a transparent region 308 of the display 300. Sub-pixel 304 (e.g., green LED) may have a corresponding adjacent mirror (e.g., tuned to reflect green light and transmit blue light) in a same layer and in a location corresponding to a transparent region 308 of the display 300. Sub-pixel 306 (e.g., red LED) may have a corresponding adjacent mirror (e.g., tuned to reflect red light and transmit blue and green light) in a same layer and in a location corresponding to a transparent region 308 of display 300. In some embodiments, sub-pixel 306 in an upper layer (e.g., red LED) may be a surface-emitting LED without an adjacent mirror, and sub-pixel 304 and 302 in lower layers (e.g., green and blue LEDs) may be edge-emitting LEDs with corresponding mirrors (e.g., tuned to reflect green light and transmit blue light, tuned to reflect blue light).

In some embodiments, mirrors are located in a region of display 300 corresponding to a transparent region of the display (e.g., transparent region 308) and enable light that is external to the display 300 to be transmitted through the display 300. For example, FIG. 3 shows light external to the display 300 that may pass through the transparent region 308 of the display 300. In some embodiments, the mirrors may be tuned to reflect a relevant wavelength range. In some embodiments, the mirrors may enable light external to the display to pass through the display 300 (e.g., transmit visible light through the display). In some embodiments, the mirrors may be positioned in a first portion of the transparent region of the display 300 in which light generated from the sub-pixels may exit the display 300 and that is adjacent to a second portion of the transparent region of the display 300 in which light external to the display is transmitted through the display. Additional details of examples of display 300 can be found in the description of FIG. 7.

In some embodiments, the display 300 may be used with passive light blockers 240 of FIG. 2E, except the passive light blocker 240 (e.g., reflective material) may cover three sides (e.g., three edges) of an edge-emitting LED (e.g., not covering a side or edge closest to a corresponding mirror where light would exit) and may or may not cover a top and/or bottom side of the LED, to direct edge-emitting light to exit the LED from a side edge that is adjacent to a corresponding mirror. In some embodiments, where a surface-emitting LED may be used (e.g., sub-pixel 306 in an upper layer), the surface-emitting LED may use a similar configuration of passive light blocker 240 of FIG. 2E.

FIG. 4 schematically illustrates examples of pixel configurations of a display. FIG. 4 shows a top view of different pixel configurations of a display. Each pixel area 410, 420, 430 and 440 comprises corresponding sub-pixels 402a-d, 404a-d, and 406a-d. For example, sub-pixel 402a, sub-pixel 402b, sub-pixel 402c, and sub-pixel 402d may comprise green LEDs. Sub-pixel 404a, sub-pixel 404b, sub-pixel 404c, and sub-pixel 404d may comprise red LEDs. Sub-pixel 406a, sub-pixel 406b, sub-pixel 406c, and sub-pixel 406d may comprise blue LEDs. Although four sub-pixels are shown in the examples of FIG. 4, any suitable number of sub-pixels and color combinations of sub-pixels may be used.

Pixel area 410 includes two sub-pixels 402a, a sub-pixel 404a, and a sub-pixel 406a arranged in a center portion of the pixel area. Pixel area 420 includes two sub-pixels 402b, a sub-pixel 404b, and a sub-pixel 406b arranged in a corner portion of the pixel area. Pixel area 430 includes two sub-pixels 402c, a sub-pixel 404c, and a sub-pixel 406c arranged in separate corners of the pixel area. Pixel area 440 includes two sub-pixels 402d, a sub-pixel 404d, and a sub-pixel 406d arranged on one side of the pixel area.

In some embodiments, a portion between adjacent sub-pixels may be covered by a passive light blocker, and a portion not covered by the sub-pixels (e.g., inactive area of the pixel area that is transparent where LEDs are not located) may be covered by a controllable light blocker.

The pixel configurations of FIG. 4 may be used with any of the embodiments described in relation to FIGS. 1A-1F, FIGS. 2A-2G, and FIG. 5. For example, the pixel configuration of FIG. 4 may comprise LEDs in a single layer, such as the embodiments described in relation to FIGS. 1A-1F. As another example, the pixel configuration of FIG. 4 may be applied to stacked sub-pixel layers of FIGS. 2A-2G, and the two sub-pixels 402a-d (e.g., green LEDs) may be in a same sub-pixel layer, sub-pixels 404a-d (e.g., red LEDs) may be in another sub-pixel layer, and sub-pixels 406a-d (e.g., blue LEDs) may be in another different sub-pixel layer.

FIG. 5 schematically illustrates an example of a pixel configuration with a lens of a display device. FIG. 5 shows a top view of a pixel area 510 with a lens 519 (e.g., microlens). The pixel area 510 may correspond to the pixel area 410 in FIG. 4, except that the pixel area includes a lens 519. For example, the sub-pixels 502, 504, and 506 may correspond to sub-pixels 402a, 404a, and 406a in FIG. 4. In some embodiments, lens 519 covers the sub-pixels 502, 504, and 506 (e.g., LEDs) in the pixel area, and does not cover a remainder of the pixel area. Although FIG. 4 shows the lens 519 covering a portion of the area covered by sub-pixels 502, 504, and 506, the lens may cover an entire portion of the area covered by sub-pixels 502, 504, and 506. In some embodiments, the lens may cover an area larger than the combined footprint of the sub-pixels 502, 504, and 506. In some embodiment, the lens may cover an area larger than 10-30% of the combined footprint of the sub-pixels 502, 504, and 506. In some embodiment, the lens may cover an area larger than 20-50% of the combined footprint of the sub-pixels 502, 504, and 506. In some embodiments, each of the sub-pixels 502, 504, and 506 can be covered by its own separate lens. In such embodiments, each lens may cover an area larger than the footprint of its respective sub-pixels 502, 504, and 506. In some embodiments, beam shaping elements may be used in place of (or in addition to) the lens structures. Use of lenses (e.g., microlenses) on an active area of the pixels (e.g., area corresponding to LEDs emitting light) may enable an image created by the LEDs to appear focused for a user (e.g., to make the image further away from the user than the surface of the glasses lens).

In some embodiments, first lenses (e.g., microlenses) cover an active area of the pixel area, and second lenses (e.g., microlenses) cover an inactive area of the pixel area corresponding to a transparent area in which light may be transmitted through the display. First lenses may enable an image created by the LEDs to appear focused for a user (e.g., be seen at a larger distance). Second lenses in transparent area of the display, where external light may be transmitted through the display, may enable the outside environment to appear focused for a user (e.g., if a user typically wears corrective lenses).

In some embodiments, a location of the display in a viewing area on the glasses in front of the eye may be in a center, edge, or top of the glasses. In some embodiments, a display of an augmented reality device comprises lenses at one consolidated level of the pixels. For example, lenses may be in a single layer of a display. In some embodiments, lenses may be in a single layer on top of a top layer of displays 100a-100f of FIGS. 1A-1F (e.g., pixel layer) or displays 200a-200g of FIGS. 2A-2G (e.g., top sub-pixel layer).

In some embodiments, a display of an augmented reality device comprises lenses at different levels of the pixels. For example, lenses may be in one or more layers of a display (e.g., displays 200a-200g FIGS. 2A-2G). In a stacked LED display, where each level of the LED display may correspond to a different color of LEDs, a corresponding lens may be placed at a level adjacent to the level of a color of LEDs.

In some embodiments, a display of an augmented reality device comprises embedded lenses. For example, reconstitution may be performed using oxide on top of lenses on a LED wafer or substrate. In some embodiments, transparent wiring is used to enable light to pass through areas adjacent to LEDs. In some embodiments, LEDs are bonded to form a display on a curved surface of a head mounted device.

FIG. 6A shows detailed features such as a reflective layer 618, light absorbing layer 620, electrodes 623, connectors 626, and redistribution layer 630 comprising interconnects 632 that include conductive wiring and conductive vias. The features shown in FIG. 6A may be applied to any suitable display (e.g., display 100a-f, display 200a-g, display 300 or any suitable display described in embodiments of present disclosure).

FIG. 6A illustrates a detailed view of the dotted box 625 where sections of a reflective layer 618 is disposed between adjacent LEDs 602. The reflective layer 618 is disposed or positioned between each LED 602 and the dielectric layer 614. The reflective layer 618 may comprise a reflective material (e.g., a metal material such as aluminum (Al) silver (Ag) or gold (Au), etc. or a combination thereof). In some embodiments, the reflective layer 618 may comprise distributed Bragg Reflector (DBR) coatings. The inclusion of the reflective layer 618 may enhance the luminance of the light output from the surface of the display and may also be used to prevent optical cross talk between LEDs 602. When electrical current flows through a LED 602, incoherent light is emitted in all directions. A reflective layer 618 enables light emitted towards the reflective layer 618 to be directed towards a viewing surface of the display. For example, the reflective layer 618 reflects light emitted from the LEDs 602 back towards a viewing surface of the display, increasing the brightness and contrast of the display. In some embodiments, a reflective layer 618 is used in applications where high visibility is relevant, such as outdoor displays or high-definition screens. The reflective layer 618 may serve as a protective barrier for the LEDs 602 from environmental factors and may extend the lifespan of the display. In some embodiments, shape the non-horizontal wall (e.g., sidewalls) of the reflector layer may comprise a parabolic or hyperbolic shape for a parabolic or hyperbolic reflector.

In some embodiments, a light-absorbing layer 620 may be disposed or positioned between adjacent LEDs 602. The light-absorbing layer 620 comprising a light-absorbing material may be disposed between the reflective layer 618 and dielectric layer 614. The light-absorbing material may significantly reduce optical crosstalk between neighboring LEDs 602. In some embodiments, the light-absorbing material comprises a metallic, resin, or polymer material.

In some embodiments, the substrate 610 comprising a plurality of singulated LEDs 602 disposed in a dielectric layer 614, may include an interconnect layer or redistribution layer 630, such as a redistribution layer (RDL). The electrodes 623 of the LEDs 602 are electrically connected to conductive features (e.g., bond pads 622) via connectors 626 through interconnects 632 in the interconnect layer or redistribution layer 630. The bond pads 622 embedded in the dielectric layer 614, can be hybrid bonded to bond pads 622 of a singulated chip or control device (e.g., a processor or controller, ROIC, etc.) embedded, in some embodiments, in the layer below what is shown in FIG. 6. The bond pads 622, electrodes 623, connectors 626, and interconnects 632 may comprise any suitable conductive material. For example, a conductive material may include metals such as copper or copper alloys, nickel, aluminum, or alloys, conductive oxide material such as indium tin oxide (ITO).

FIGS. 6B-6C show a schematic of an example method to form a display through heterogenous pixel integration, where singulated LEDs 602 from RGB wafers can be integrated to form a composite RGB pixel. In some embodiments, the example method shows forming a substrate (e.g., a reconstituted substrate of LEDs), but can be applied to form a reconstituted substrate of LEDs and control devices). In some embodiments, singulated LED 602 may correspond to (e.g., be similar to or same as) LEDs or sub-pixels 202a-g, 204a-g, and 206a-g of FIGS. 2A-2G. In some embodiments, the example method may be applied to form a reconstituted substrate of different types of LEDs and may correspond to (e.g., be similar to or same as) substrate 101a-f with different types of LEDs or sub-pixels 102a-f, 104a-f, 106a-f of FIGS. 1A-1F. In some embodiments, the singulated LEDs may apply to any suitable LED described in the present disclosure.

At block 60, the method includes singulating a wafer to form pixel-size chips or chiplets. For example, a wafer of singulated LEDs 602 may be placed on a tape frame or temporary carrier 616 and singulated to form LED chips or chiplets. The singulated LED chips or chiplets may be about 1×1 micron², about 5×5 micron², about 10×10 micron², to about 40×40 micron² or any suitable LED size for a pixel. In some embodiments, any suitable wafer (e.g., wafer of blue LEDs, wafer of green LEDs, wafer of any suitable color, wafer of control devices, etc.) may be placed on a tape frame and singulated. The method may further include stretching the temporary carrier 616 to space apart neighboring chips or LEDs (e.g., singulated LEDs 602), shown at 61.

At block 61, the method includes spacing apart singulated chips or chiplets. In some embodiments, the method of spacing singulated LED chips (e.g., singulated LEDs 602) from diced wafers may include separation via dicing tape expansion (e.g., stretching temporary carrier 616). For example, the temporary carrier 616 may be stretched to create uniform spacing between neighboring singulated LEDs (e.g., singulated LEDs 602). A spacing of about 1 to 40 microns between neighboring singulated LEDs (e.g., singulated LEDs 602) may be formed as based on a desired pixel size. In some embodiments, after stretching the chiplets on a first tape, the spaced-apart chiplets may be transferred to a second tape for a second stretching operation. Multiple stretching operations may be performed to obtain the desired lateral spacing between the chiplets before subsequent operations. One of the subsequent operations may comprise transferring the chiplets to a carrier.

At block 62, the method includes transferring the singulated chips or chiplets to a carrier substrate. For example, singulated LEDs 602 are transferred to a carrier substrate 650 via bonding or adhesive. Before or after transferring, diffusion regions may be removed from the LEDs and first electrodes 623 may be formed. In some embodiments, both electrodes (e.g., first and second electrodes) may be formed to the LEDs based on the design. The method may include forming a reflective layer 618 over the plurality of singulated LED (e.g., singulated LEDs 706). The reflective layer 618 may comprise a reflective metal (e.g., Ag, Au, or Al, etc.) or DBR coatings. One or more dielectric layers (e.g., adhesion, isolation, passivation, barrier, etc.) may be deposited before and/or after the reflective layer 618 is formed. In some embodiments, the reflective layer may comprise of a distributed Bragg reflector. In some embodiments, a reflective material (e.g., reflective layer 618) may be coated on non-light-emitting sides of each LED 602. In some embodiments, a light-absorbing layer may be disposed or positioned between adjacent LEDs 602. The light-absorbing layer comprising a light-absorbing material may be disposed between the reflective layer 618 and a dielectric layer 614. The light-absorbing material may significantly reduce optical crosstalk between neighboring LEDs 602. In some embodiments, the light-absorbing material comprises a metallic, resin, or polymer material.

At block 63, the method includes forming a reconstitution dielectric over the singulated chips or chiplets. For example, the dielectric layer 614 is formed over the reflective layer 618. The dielectric layer 614 may comprise silicon oxide or a suitable dielectric material tuned to transmit a specific wavelength range (e.g., corresponding to a color of light emitted from an LED of bonded adjacent substrate behind/below dielectric layer 614). In some embodiments, the transparent region 108a-f of FIGS. 1A-1F or the transparent region 208a-g of FIGS. 2A-2G may comprise portions of the dielectric layer 614.

At block 64, the method includes forming electrical connectors to the chip or chiplets. For example, electrical connectors 626 are formed to contact the electrodes 623 of singulated LEDs 602. The method may include forming vias 628a and 628b through the dielectric layer 614. The vias 628a-b may enable electrical connections through the dielectric layer 614 to neighboring substrates via hybrid bonding. The electrical connectors 626 and vias 628a-b may comprise a same or different material and may be any suitable conductive material such as those described in the present disclosure. In some embodiments, the method of forming the electrical connectors 626 and vias 628a-b may comprise depositing or coating a suitable adhesion layer over a patterned cavity corresponding to the electrical connectors 626 and/or vias 628a-b, over filling the patterned cavity with a suitable conductive layer, and planarizing the conductive layer to remove unwanted materials (e.g., overburden of material, excess material, a portion of material to help planarize a surface). The unwanted materials may comprise portions of the conductive layer, the adhesion layer, and the dielectric layer 614. In some embodiments, the connectors 626 and vias 628a-b may comprise wirebonds, formed by wirebonding operations. In other embodiments, the connectors 626 and vias 628a-b may be formed by 3D printing methods or screen printing methods.

At block 65, the method includes forming a direct bonding interface (DBI) layer (e.g., bottom DBI layer). For example, the method comprises forming a redistribution layer 640 comprising conductive features or bond pads 622 and interconnects 632 in a dielectric layer.

At block 66, the method includes transferring the reconstituted wafer to another substrate. For example, the method includes transferring the reconstituted singulated LEDs 602 and redistribution layer 640 to substrate 652 (e.g., another carrier or a target wafer) and removing the first carrier 650. In some embodiments, the reconstituted wafer comprising singulated LEDs 602 can be transferred to or hybrid bonded to another reconstituted wafer (comprising LEDs and/or control device) or another wafer comprising control devices (e.g., control or controller device wafer, device wafer, ROIC wafer, full wafer, etc.). The method may include forming second electrodes 633 of the LEDs 602. The method may include forming another DBI layer (e.g., top DBI layer). For example, the method includes forming a redistribution layer 642 comprising interconnects 632 and bond pads 622 in a dielectric layer.

In some embodiments, the method shown in FIGS. 6B-6C can be modified to form any suitable substrates such as those mentioned in the present disclosure. For example, at block 62, method may include multiple transfer steps, where different types of LEDs (e.g., singulated wafer of red LEDs, singulated wafer of green LEDs, singulated wafer of blue LEDs, etc.) and/or singulated control devices may be transferred.

In some embodiments, the method includes hybrid bonding to electrically connect each control device to one or more of the LEDs to form a pixel. For example, at block 66 the substrate 652 may be a processor substrate (e.g., processor wafer, control wafer, reconstituted substrate with processors or control devices). Hybrid bonding the substrate to a processor substrate may electrically connect a control device to one or more LEDs of the second substrates. Each control device and the one or more LEDs electrically connected thereto may form a pixel.

In some embodiments, singulated LEDs of different color LED wafers may be transferred at block 62 and bonded to a processor substrate to form the displays 100a-f of FIGS. 1A-1F. The redistribution layer 642 may comprise second electrodes 633 and may not comprise bond pads 622 and interconnects 632.

In some embodiments, the reconstituted substrate at block 66 may be hybrid bonded to other reconstituted substrates via redistribution layer 642. The LEDs in each reconstituted substrate may be electrically connected to control devices through vias 628a and direct metal bonds made through bond pads 622 of the reconstituted substrates.

In some embodiments, where there are more than one stacked layer, the display may further comprise light guides. For example, the method may include forming deep-trench isolation with metal fill that guides light emitted from the LEDs of at least of the first substrates or the second substrate to a surface of the display. For example, the method may include forming channels with metal coatings to form light guides. In some embodiments, the method may include forming a dielectric fill on the metal coatings in the channels.

FIGS. 7A-7B schematically illustrates example views of a pixel configuration in a display device, according to some embodiments. In some embodiments, FIGS. 7A-7B show more detail of an example cross sectional view of a pixel configuration in a display device of FIG. 3.

FIG. 7A shows a pixel 723a of a display device. The display device comprises three multilayer stacks (e.g., multilayer stack 706a, multilayer stack 706b, and multilayer stack 706c). In some embodiments, the multilayer stack 706a corresponds to sub-pixels 306 disposed on substrate 305, the multilayer stack 706b corresponds to sub-pixels 304 disposed on substrate 303, and the multilayer stack 706c corresponds to sub-pixels 302 disposed on substrate 301 of FIG. 3. In some embodiments, the waveguides 710a, 710b, and 710c and/or DTI 725 may correspond to a transparent region 308 of FIG. 3. The DTI 725 defines (e.g., electrically separates or provides separation of pixel areas or provides a gap between pixels) each pixel of the display (e.g., display 300). In some embodiments, the DTI 725 comprises metal, polySi, reflective coating, oxide, dielectric, or a combination thereof. In some embodiments, the DTI 725 may comprise a single fill material (e.g., metal, polySi, reflective coating). In some embodiments, the DTI 725 may comprise an inner portion comprising oxide or dielectric, and an outer portion comprising metal, polySi, reflective coating. An inner portion comprising oxide or dielectric may correspond to a transparent region 308.

Each multilayer stack may comprise one or more edge-emitting LEDs. A size of an edge-emitting LED may be about be 5-10 microns. Each edge-emitting LED may comprise a respective active layer (e.g., active layer 712a, active layer 712b, active layer 712c). The active layer may have a thickness of about 100 nm or less than about 100 nm. Disposed on top and bottom of each active layer or active region is a respective lightguide layer (e.g., lightguide layer 716a, lightguide layer 716b, and lightguide layer 716c). The lightguide layers collect light emitted from the active layer or active region and directs it to the edges of the respective multilayer stack (e.g., through optical principle of total internal reflection (TIR)).

The first multilayer stack 706a, second multilayer stack 706b, and third multilayer stack 706c each comprise one or more waveguide 710a, waveguide 710b, waveguide 710c, respectively. A size (e.g., width, length, and/or height) of the waveguides 710a-c may be about 500 nm. A width of the waveguides 710a-c (e.g., along y-axis) may be about 100 nm, 200 nm, 500 nm, or 1 micron, or less than about 100 nm, less than about 200 nm, less than about 500 nm, or less than about 1 micron. In some embodiments, the thickness of the waveguides 710a-c may be less than about 25 microns, or less than about 20 microns, or less than about 15 microns, or less than about 10 microns thick. In some embodiments, the edge-emitting LEDs comprise optical coatings on the exterior surfaces of each the edge-emitting LEDs to prevent light leakage from the respective active layers. For example, the other side surfaces of the edge-emitting LEDs that are not adjacent to a waveguide 710a-c may include a reflective surface to guide light to the waveguide 710a-c.

In some embodiments waveguides 710a-c may be referred to as reflecting blocks, reflector blocks, or reflector cubes. Each waveguide (e.g., waveguide 710a, waveguide 710b, and waveguide 710c) may be disposed in an opening of a respective multilayer stack (e.g., multilayer stack 706a, multilayer stack 706b, and multilayer stack 706c). Each waveguide 710a-c may comprise a metalized reflective film, reflecting surface, or reflecting material (e.g., reflector 720, reflector 721, and reflector 722) embedded or disposed in a material layer (e.g., oxide or dielectric material). The material layer may comprise an oxide material, an oxide fill, glass or other silica derived glasses, or any other suitable optically transparent material. The reflector 720-722 may guide or reflect light emitted from an active layer 712a-c of a corresponding edge-emitting LED 119a-c to the surface of the display.

In some embodiments, the reflectors 720-722 may be referred to as mirrors. The reflector (e.g., reflector 720, reflector 721, and reflector 722) may be a semi-transparent element, a beam splitting element or layer, or a partial mirror (e.g., a partially reflecting or partially transmitting mirror).

In some embodiments, the reflective surface or reflector 721 of the second multilayer stack 706b is capable of reflecting light emitted from the active layer 712b of the second multilayer stack 706b and transmitting light emitted from the active layer 712a of the first multilayer stack 706a. The reflective surface or reflector 721 may be a dichroic mirror. The reflective surface or reflector 721 may be a plurality of alternating thin films of varying materials of varying indices of refraction configured to allow for the transmission of the wavelength band emitted by the active layer 712a of the first multilayer stack 706a while reflecting the wavelength band emitted by the active layer 712b of the second multilayer stack 706b.

In some embodiments, the reflecting surfaces (e.g., reflectors 720-722, mirrors, or any other suitable reflective surfaces mentioned in the present disclosure) may be created using a metallization process. The metallization process may involve the deposition and patterning of various metals on an active side of the substrate (e.g., multilayer stack). Metals used in the fabrication of mirrors (e.g., micro mirrors) include aluminum (Al), silver (Ag), gold (Au), chromium (Cr), and indium tin oxide (ITO) or a combination thereof. For example, a thin layer of aluminum may be deposited on a side of a substrate to form the reflector, reflective surface, or micro mirror. An aluminum layer may be deposited using physical vapor deposition (PVD) techniques such as sputtering or evaporation. The deposited aluminum layer may be patterned using photolithography and etching processes to define the reflecting surfaces or mirror structures.

In some embodiments, any of the multilayer stacks comprise an insulation layer. The insulation layer may comprise an oxide, nitride, or other suitable material to provide spacing between the metallization layer and the light pipe and active layer. In some embodiments there are no insulating layers.

In some embodiments, the display device (e.g., any suitable display mentioned in the present disclosure) may comprise vias, interconnects, and integrated circuits (IC). In some embodiments, each pixel or sub-pixel may have a corresponding IC for driving the pixel. The vias and interconnects may connect and communicatively couple electrical components of the multilayer stack to integrated circuits of a display device.

Each edge-emitting LED may be communicatively coupled to an independent integrated circuit (IC) to control the color output. In some embodiments, the edge-emitting LEDs of one pixel may be communicatively coupled to an independent integrated circuit (IC) to operate as a single pixel 723a. In some embodiments, a control device may be coupled to a plurality of pixels. In some embodiments, each multilayer stack 706a-c comprises a respective metallization layer 718a-c disposed on the top and bottom of the multilayer stack or on the outside faces of the respective lightguide layers 716a-c (e.g., light pipe layers).

In some embodiments, the display (e.g., any suitable display such as those mentioned in the present disclosure) is an RGB display and the active layer 712a is capable of emitting red light, the active layer 712b is capable of emitting green light, and the active layer 712c is capable of emitting blue light. In some embodiments, the display comprises one color or wavelength. In some embodiments, the display is capable of emitting light of two colors, or a combination thereof. Blue and ultraviolet (UV) light may excite phosphors that emit higher wavelengths, so it may be advantageous to position a blue edge-emitting LED on top of the display (e.g., active layer 712c emits blue light).

Between each the edge-emitting LEDs and respective waveguides may exist a plurality of optical layers. The optical layers may change a polarization of light, an amplitude of light, a direction of light, a dispersion of light, or a phase of light. The display (e.g., any suitable display such as those mentioned in the present disclosure) may use any suitable combination of colors or any suitable stacked order of colors.

In some embodiments, the reflector blocks or reflector cubes are superimposed on one another (e.g., overlapping in a top down view) and may comprise reflecting elements to allow the transmission of light therebelow. For example, the openings of each the multilayer stacks 706a-c are superimposed, and each respective waveguides 710a-c or reflecting blocks are superimposed. In some embodiments, the openings for each multilayer stack are not superimposed and may comprise reflector blocks or reflector cubes comprising a metal reflector.

In some embodiments each the respective reflector cubes or waveguides 710a-c are directly bonded to the neighboring reflecting block or waveguide 710a-c. In some embodiments each the respective reflector block or waveguides 710a-c are hybrid bonded to the neighboring reflecting block or waveguide 710a-c.

A method of forming a waveguide (e.g., waveguide 710a, 710b, 710c) may include providing a multilayer stack (e.g., multilayer stack 706a, 706b, 706c). In some embodiments, each multilayer stack may be at the wafer level. In some embodiments, the multilayer stack may be provided by forming layers at a wafer level or providing individual wafer levels and stacking them together.

The method may include forming openings in a multilayer stack. For example, the method may include etching first openings in a multilayer stack. In some embodiments, multilayer stack may be on a carrier substrate, and forming the openings may comprise etching the multilayer stack from a first surface to a second surface opposite the first surface of multilayer stack (e.g., through multilayer stack). The openings may be etched via a wet etch, a dry etch, or any suitable etching technique. The openings may be formed to provide for a particular shape or geometry of the reflector. In some embodiments, the opening may have a shape of a triangle.

In some embodiments, the method includes forming openings that are divots. For example, the method may include partially etching the multilayer stack (e.g., openings are not formed from a first surface to a second surface opposite the first surface of the multilayer stack). The opening may be etched through an emissive layer such that a reflector formed in the opening may overlap a thickness or height of the emissive layer. For example, at least an emission portion (e.g., emissive layer) of the multilayer stack may be etched to have sloped sidewalls, and other portions (e.g., lightguide layer) of the multilayer stack may not be etched or fully etched (e.g., etched through the lightguide layer). The method may include forming a first dielectric layer in the first opening in multilayer stack. The first dielectric layer may comprise an oxide layer, a nitride layer, a plurality of layers of oxide and/or nitride, or layer of optically tuned material.

The method may include forming a reflective layer (e.g., reflector) on the first dielectric layer in the first opening. The reflective layer may comprise a metal layer, a plurality of thin films, a dichroic layer, a dichroic mirror layer. In some embodiments, the reflective layer (e.g., reflector) covers or overlaps a thickness of the of the emission portion.

The method may include forming a second dielectric layer on the reflective layer on the first dielectric layer in the first opening. The second dielectric layer may be a fill layer comprising fill material. A fill material may comprise any suitable fill material such as a silicate material, a non-transparent or opaque semiconductor material fill, or any suitable material. In some embodiments, a non-transparent or opaque fill material may be used as light is not transmitted through the bottom of the waveguide.

The method may include removing a portion of the multilayer stack around the first dielectric layer. Removing a portion of the multilayer stack may be done by etching. The etching may produce an angle between the angle of the edge-emitting LED opening and the angle of the reflector or reflective layer. The angle may be about 45 degrees or less than about 90 degrees. In some embodiments, the shape of the reflector may be a triangular prism, a pyramid, or any suitable shape.

The method may include depositing a material (e.g., dielectric, oxide, optically tuned material, third dielectric layer) to fill the removed portion of the multilayer stack around the first dielectric layer. In some embodiments, optically tuned is defined as low absorption of light within the material. A low absorption may include absorbance rate of less than about 2% of a particular wavelength per unit-distance traveled. In some embodiments, a low absorption may include an absorbance rate of less than about 10%, or less than about 5%, or less than about 3%, or less than about 1% of a particular wavelength per unit-distance traveled.

The waveguide may reflect and transmit light emitted from the active layer. In some embodiments, the waveguide comprises an oxide material, a nitride material, a combination thereof, or any suitable dielectric material. In some embodiments, the waveguide comprises multi-layer fill of suitable material.

In some embodiments, the method includes etching portions of the metallization layer of the multilayer stack. In some embodiments, the metallization layer of the multilayer stack may be formed (e.g., deposited or patterned) after the waveguide is formed.

In some embodiments, the multilayer stack may be etched or partially etched to form a larger separation for dicing. For example, a spacing between adjacent LEDs may be increased to have a larger separation for dicing.

FIG. 7B shows a pixel 723b of a display device. The display device in FIG. 7B comprises a substrate 706d (e.g., layer, wafer, etc.) disposed on two multilayer stacks (e.g., multilayer stack 706a and multilayer stack 706b). In some embodiments, the display device in FIG. 7B is similar to the display device in FIG. 7A except the substrate 706d is used in place of the multilayer stack 706c. In some embodiments, the sub-pixel 749 corresponds to sub-pixel 306 disposed on substrate 305, the multilayer stack 706b corresponds to sub-pixel 304 disposed on substrate 303, and the multilayer stack 706c corresponds to sub-pixel 302 disposed on substrate 301 of FIG. 3. In some embodiments, the waveguides 710a, 710b, and 750 and/or DTI 725 may correspond to a transparent region 308 of FIG. 3.

The substrate 706d may comprise a plurality of surface emitting LEDs and light guides or waveguides (shown in FIG. 7B as LED 749 and waveguide 750). The surface emitting LEDs may comprise a phosphor. The substrate 706d may comprise waveguides 750 (e.g., waveguide block comprising fill material or glass) disposed in openings of the substrate 706d. The waveguides 750 may be superimposed over top the waveguides 710a and 710b of the multilayer stacks 706a and 706b. The waveguides 750 may comprise optically tuned material that allows for the transmission of light emitted from the first multilayer stack 706a and second multilayer stack 706b. In some embodiments, the waveguides 710a and 710b comprises a dielectric, an oxide, or a combination thereof optically tuned to allow for the transmission of light emitted by the active layer of the first multilayer stack 706a and the transmission of light emitted by the active layer of the second multilayer stack 706b.

In some embodiments, the substrate 706d is attached (e.g., directly bonded, hybrid bonded) to the multilayer stack 706b, and the multilayer stack 706b is attached (e.g., directly bonded, hybrid bonded) to the multilayer stack 706a. The waveguide 750 may be directly bonded or hybrid bonded to the waveguide 710b. The waveguide 710b may be directly bonded or hybrid bonded to the waveguide 710a.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 1B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 1A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 811 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

It is contemplated that any combination of the methods described above may be used to form a display whether or not expressly recited herein.

The embodiments discussed above are intended to be illustrative and not limiting. One skilled in the art would appreciate that individual aspects of the display and display device, and methods discussed herein may be omitted, modified, combined, and/or rearranged without departing from the scope of the disclosed subject matter.

1. A method of forming a display comprising:
forming a plurality of LEDs on a substrate, wherein each pixel of the display comprises one or more LEDs of the plurality of LEDs; and
forming a transparent region of the display, wherein the transparent region transmits light external to the display through the display.

2. The method of claim 1, further comprising:
forming a plurality of passive light blockers, each passive light blocker overlapping with the one or more LEDs of a corresponding pixel of the display when viewed from top down or bottom up, preventing light external to the display from transmitting through the display in a region corresponding to the one or more LEDs of the corresponding pixel.

3. The method of claim 2, wherein each passive light blocker comprises a metal layer.

4. The method of claim 2, wherein each passive light blocker comprises a singulated chip.

5. The method of claim 4, wherein transparent wiring electrically connecting one or more singulated chips overlaps with a corresponding transparent region of the display when viewed from top down or bottom up.

6. The method of claim 1, further comprising:
forming a plurality of passive light blockers to cover a bottom and side surfaces of each LED, each passive light blocker preventing light external to the display from transmitting through a corresponding LED.

7. The method of claim 6, wherein each passive light blocker comprises a metal layer.

8. The method of claim 1, further comprising:
forming a controllable light blocker overlapping with the transparent region of the display when viewed from top down or bottom up, the controllable light blocker comprising a switchable material, wherein:
in response to applying a bias to electrodes that are electrically coupled to the switchable material, the switchable material transmits light external to the display through the display in the transparent region of the display; and
in response to not applying a bias to the electrodes that are electrically coupled to the switchable material, the switchable material blocks light external to the display from transmitting through the display in the transparent region of the display.

9. The method of claim 8, wherein the switchable material comprises liquid crystal material.

10. The method of claim 1, wherein:
the one or more LEDs of each pixel is formed in a center portion of a corresponding pixel area when viewed from top down or bottom up.

11. The method of claim 1, wherein the one or more LEDs of each pixel is formed in one corner of a corresponding pixel area when viewed from top down or bottom up.

12. The method of claim 1, wherein the one or more LEDs of each pixel is formed in corresponding corners of a corresponding pixel area when viewed from top down or bottom up.

13. The method of claim 1, wherein the one or more LEDs of each pixel is formed in one side of a corresponding pixel area when viewed from top down or bottom up.

14. The method of claim 1, further comprising:
attaching a plurality of lenses to the display, wherein the plurality of lenses overlap the plurality of LEDs when viewed from top down or bottom up.

15. The method of claim 14, wherein each lens corresponds to a pixel of the display.

16. The method of claim 1, further comprising:
attaching a plurality of first lenses to the display, wherein the plurality of first lenses overlap the plurality of LEDs when viewed from top down or bottom up; and
attaching a plurality of second lenses to the display, wherein the plurality of second lenses overlap the transparent region of the display when viewed from top down or bottom up.

17-37. (canceled)

38. A display comprising:
a plurality of LEDs on a substrate, wherein each pixel of the display comprises one or more LEDs of the plurality of LEDs; and
a transparent region of the display, wherein the transparent region transmits light external to the display through the display.

39. The display of claim 38, further comprising:
a plurality of passive light blockers, each passive light blocker overlapping with the one or more LEDs of a corresponding pixel of the display when viewed from top down or bottom up, preventing light external to the display from transmitting through the display in a region corresponding to the one or more LEDs of the corresponding pixel.

40. The display of claim 39, wherein each passive light blocker comprises a metal layer or a singulated chip.

41-44. (canceled)

45. The display of claim 38, further comprising:
a controllable light blocker overlapping with the transparent region of the display when viewed from top down or bottom up, the controllable light blocker comprising a switchable material, wherein:
in response to applying a bias to electrodes that are electrically coupled to the switchable material, the switchable material transmits light external to the display through the display in the transparent region of the display; and
in response to not applying a bias to the electrodes that are electrically coupled to the switchable material, the switchable material blocks light external to the display from transmitting through the display in the transparent region of the display.

46-71. (canceled)
